(19) United States
(12) Patent Application Publication
(10) Pub. No.: US 2007/0024184 A1
(43) Pub. Date: Feb. 1, 2007

(54) Full-color organic electroluminescent display device with low power consumption

(76) Inventors: Chien-Yuan Feng, Chu-Nan (TW); Ting-Chou Chen, Chu-Nan (TW); Wen-Jeng Lan, Chu-Nan (TW); Chien-Chih Chiang, Chu-Nan (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/443,038

(22) Filed: May 31, 2006

(30) Foreign Application Priority Data
Aug. 1, 2005 (TW) 094126104

(51) Int. Cl. H01J 1/62; H01J 63/04

(52) U.S. Cl. 313/504

(57) ABSTRACT

A Full-color organic electroluminescent display device with low power consumption includes a first electrode provided on the surface of a color filter, a first organic light emitting unit for generating a first light and a fourth organic light emitting unit for generating a fourth light respectively provided on the surface of the first electrode. The first light passes through a first photo-resist and filtered for generating a first colored light. And, the fourth organic light emitting unit provides a second photo-resist and a third photo-resist on the vertical extension place thereof. The fourth light passes through the second photo-resist and filtered for generating a second colored light, passes through the third photo-resist and filtered for generating a third colored light. Thus, the first colored light, second colored light, and third colored light are used to be mixed and collocated for forming full-color light emitting.

### FIELD OF THE INVENTION

The present invention relates to an organic electroluminescent display device, and more particularly, to a full-color organic electroluminescent display device with low power consumption, not only improving the light transmission and color saturation, but also reducing power consumption and extending the element lifetime thereof.

### BACKGROUND OF THE INVENTION

The key point of the display device development is to show a full-color display effect. There are two generally methods in organic electroluminescent display device (OLED) as following:
1. To provide the organic light emitting elements for generating primary colors (Red, Green, and Blue) respectively and independently (side by side), mix and collocate such primary colors in proper ration to show a full-color display effect. However, the organic light emitting elements for generating different colored light are made by a lot of times evaporation processes, not only manufacturing more complicated, but also evaporation aligning more difficult. Thus, the variation yield and cost will increase.
2. To provide at least one organic light emitting element for generating white light, collocating color filter to show a full-color display effect.

Referring to FIG. 1, a prior art organic electroluminescent display device 200 with color filtering includes a color filter 10, which provides a Black Matrix 13 on a substrate 11; a color-filtering layer 15 for filtering color formed on the partial surface of the Black Matrix 13, and the partial surface of the substrate 11 without the Black Matrix 13, which includes a first photo-resist (G) 151, a second photo-resist (B) 153, and a third photo-resist (R) 155. And, it could be formed an overcoat layer 17 or a barrier layer for following processing.

Further, a first electrode 21 of an organic light emitting element 20 is provided on the surface of the overcoat layer 17 or barrier layer; an organic light emitting unit 23 and a second electrodes 25 are provided in turn on the partial surface of the first electrode 21; conducting current through the first electrode 21 and the second electrodes 25 for emitting a white light S from the organic light emitting unit 23. After the white light S passing through color-filtering layer 15, it will be color filtering to form the primary color, Green (G), Blue (B), and Red (R), as L1, L2, and L3, to mix and collocate for showing full-color display.

By way of the color filter 10 providing, the organic electroluminescent display device 200 only demands a organic light emitting unit 23 to generate a white light S. Therefore, the time of evaporation processes will be reduced, and the evaporation aligning will be easier. However, according to the wave length of white light spreading so wide, it causes the light penetrates through the color-filtering layer 15 badly, and then affecting the light brightness and color saturation of the organic electroluminescent display device 200.

### SUMMARY OF THE INVENTION

It is a primary object of the present invention to provide an organic electroluminescent display device with low power consumption, thereby reducing the times of evaporation processes to show the full-color display effect, not only simplifying the process, but also efficiently increasing the yield of products.

It is a secondary object of the present invention to provide an organic electroluminescent display device with low power consumption, not only applied to passive matrix organic electroluminescent display device, but also active matrix organic electroluminescent display device, and then simplifying the difficulty of alignment and evaporation for reducing the cost.

It is another object of the present invention to provide an organic electroluminescent display device with low power consumption, thereby qualifying by the color filter for well performance of the color and preventing the decline of the primary color from showing the color shift and low saturation.

It is another object of the present invention to provide an organic electroluminescent display device with low power consumption, not only simplifying the difficulty of alignment and process, but also efficiently increasing the light transmission and color saturation, and then reducing the power consumption and extending the lifetime of elements.

To achieve the previous mentioned objects, the present invention provides a full-color organic electroluminescent display device with low power consumption, comprising a color filter, providing a first color resist, second color resist, and third color resist on the partial surface of a transparent substrate; a first electrode provided on the partial surface of the color filter; a first organic light emitting unit provided on the surface of the first electrode of the vertical extension place of the first color resist; a fourth organic light emitting unit provide on the surface of the first electrode of the vertical extension place of the second and third color resist; a second electrodes provided on the partial surface of the first and fourth organic light emitting unit.

### BRIEF DESCRIPTION OF THE DRAWINGS

FIG. 1 depicts a schematic cross sectional view of a conventional prior art organic electroluminescent display device;

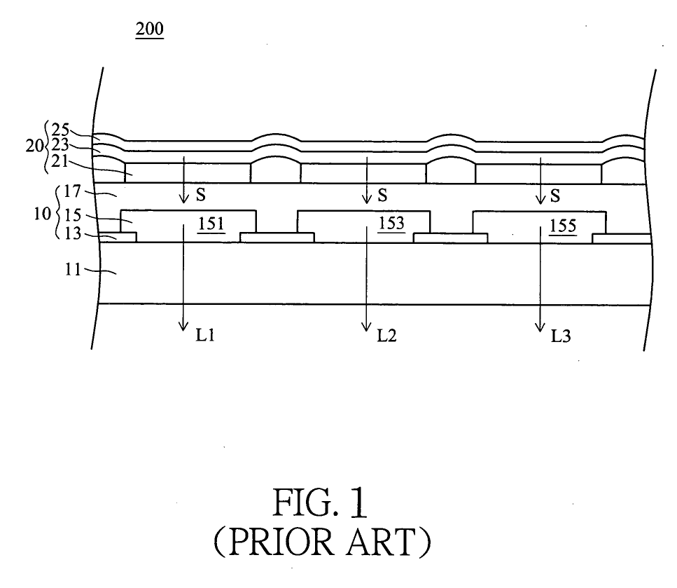

FIG. 2 depicts a schematic cross sectional view of an organic electroluminescent display device according to one embodiment of the present invention;

FIG. 3 depicts a schematic cross sectional view of another embodiment of the present invention;

FIG. 4 depicts a schematic cross sectional view of another embodiment of the present invention;

FIG. 5 depicts a schematic cross sectional view of other embodiment of the present invention;

FIG. 6 depicts a schematic cross sectional view of an active matrix organic electroluminescent device according to one embodiment of the present invention; and

FIG. 7 depicts a schematic cross sectional view of another embodiment of the present invention.

It will be understood that the figures are not to scale since the individual layers are too thin and the thickness differences of various layers too great to permit depiction to scale.

### DETAILED DESCRIPTION OF THE INVENTION

The structural features and the effects to be achieved may further be understood and appreciated by reference to the presently preferred embodiments together with the detailed description.

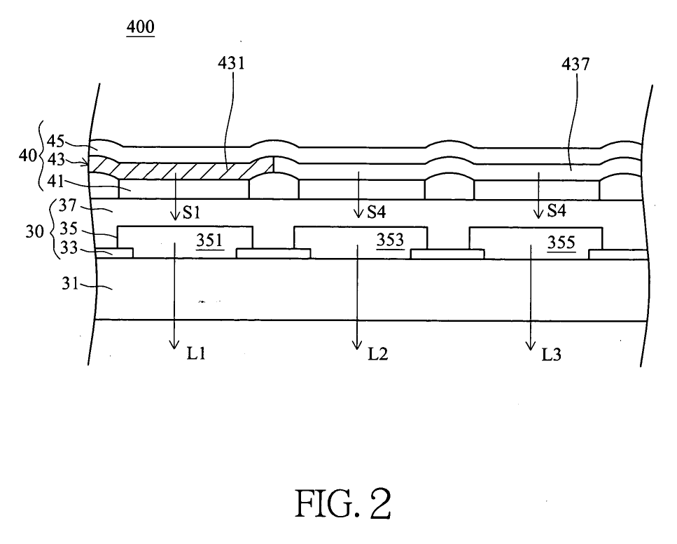

Referring to FIG. 2 for a schematic cross sectional view of one embodiment of the present invention, the organic electroluminescent display device 400 comprises at least one organic light emitting element 40 on the partial surface of a color filter 30. The color filter 30 comprising at least one black matrix 33 on the partial surface of a transparent substrate 31. Further, a color-filtering layer 35 (or photo-resist) for color filtering function provided on the partial surface of the black matrix 33 and the area uncovered black matrix 33 of the transparent substrate 31. The color-filtering layer 35 comprises a first photo-resist 351, second photo-resist 353, and third photo-resist 355. And, a flat barrier unit 37, such as an overcoat layer, a barrier layer, or the both, are covered on the black matrix 33 and the color-filtering layer 35.

A first electrode 41 is provided on the surface of the color filter 30, and a first organic light emitting unit 431 provided on the vertical extension place of the first photo-resist 351. Further, a fourth organic light emitting unit 437 provided on the vertical extension place of the second photo-resist 353 and third photo-resist 355. The first organic light emitting unit 431 will generate a first light S1, and the fourth organic light emitting unit 437 will generate a fourth light S4, when an operation current passing through the first electrode 41 and second electrode 45.

The first light S1 generated from the first organic light emitting unit 431, will pass through the first photo-resist 351, and filtered to generate a first colored light L1. The fourth light S4 generated from the fourth organic light emitting unit 437, will respectively pass through the second photo-resist 353 and third photo-resist 355, and filtered to generate a corresponding second colored light L2 and third colored light L3. To mix and collocate the first colored light L1, second colored light L2, and third colored light L3 will shows a full-color display effect on the organic electroluminescent display device 400.

In view of an embodiment of the present invention, the first light S1 generated from the first organic light emitting unit 431 is a blue light source, and the fourth light S4 generated from the fourth organic light emitting unit 437 is selected by a white light source S or a complementary light source with the first light S1, such as yellow light source or orange light source. And, the first photo-resist 351, second photo-resist 353, and third photo-resist 355 are respectively as a blue photo-resist B 351, green photo-resist G 353, and red photo-resist R 355; either, as a blue photo-resist B 351, red photo-resist G 353, and green photo-resist R 355. Therefore, the first light S1 (blue light) filtered from the first photo-resist (blue photo-resist) 351, will generate a first colored light L1 (blue light); and the fourth light S4 (orange light) filtered from the second photo-resist (green photo-resist) 353 and third photo-resist (red photo-resist) 355, will respectively generate a second colored light L2 (green light) and third colored light L3 (red light). To mix and collocate the first colored light L1 (blue light), second colored light L2 (green light), and third colored light L3 (red light) by proper proportion and the complementariness each other, will shows a full-color display effect on the organic electroluminescent display device 400.

Of course, in view of another embodiment of the present invention, the first light S1 generated from the first organic light emitting unit 431, is also as a red light; and the fourth light S4 generated from the fourth organic light emitting unit 437, is as a white light source or cyan light source. In this time, the first photo-resist 351, second photo-resist 353, and third photo-resist 355 are respectively as a red photo-resist, green photo-resist, and blue photo-resist; either, as a red photo-resist, blue photo-resist, and green photo-resist; thus, showing a full-color display effect on the organic electroluminescent display device 400 is achieved also.

According to the color filtering layer 35 only allows specific wavelength field of light source passing for filtering colored light, such as if the first photo-resist 351 is designed for allowing only wavelength 400 nm˜500 nm light source to pass, then the first photo-resist 351 will filter and isolate other light source from the wavelength field out of 400 nm˜500 nm, allowing the wavelength 400 nm˜500 nm colored light to pass, which is a blue light as eyeball received, when after the light source as the white light source S passing through the first photo-resist 351. However, when filtering the colored light, the wavelength field out of 400 nm˜500 nm, will be filtered and isolated by the first photo-resist 351. Therefore, as far as the white light source S is concerned the first photo-resist 351 does not have well transmittance for light source, which is around 25%; thus, comparatively reducing the light intensity.

Oppositely, if the wavelength of the first light S1 is around the field out of allowance wavelength field by the first photo-resist 351, then as far as the first light Si is concerned the first photo-resist 351 have well transmittance, such as the wavelength of the first light S1 is around 420 nm˜470 nm (blue light source). Further, when the wavelength field allowance by the first photo-resist 351 is as foregoing mentioned around 400 nm˜500 nm (blue photo-resist), the most first light S1 will be able to pass through the first photo-resist 351 completely, such as in view of a embodiment of the present invention, the transmittance is up to 80%. Therefore, comparatively the prior art as the organic electroluminescent display device 200 with white light source S as the light source, the present invention discloses well light transmittance and intensity, of course, relatively reducing the power consumption and extending the lifetime of element.

The fourth light S4 is as an orange light source, and the corresponding second photo-resist 353 and third photo-resist 355 are respectively as a green photo-resist and red photo-resist. According to the fourth light S4 (orange light source) is mixed by proper proportion of green light source and red light source. Therefore, after the fourth light S4 (orange light source) passing through the second photo-resist (green photo-resist) 353 and third photo-resist (red photo-resist) 355, will respectively filter and isolate the red light source and green light source of the fourth light S4 (orange light source), and respectively generate the second colored light L2 (green light source) and third colored light L3 (red light source). Thus, as far as the fourth light S4 is concerned the second photo-resist 353 and third photo-resist 355 provide better transmittance than the prior art organic electroluminescent display device 200, such as up to 40%.

Therefore, according to the organic electroluminescent display device 400 of the present invention, the light transmittance will increase from the first light S1 and fourth light S4 to the color filtering layer 35, and further increasing the light transmittance, light intensity, and color saturation of the organic electroluminescent display device 400, extending the lifetime of element and reducing the power consumption.

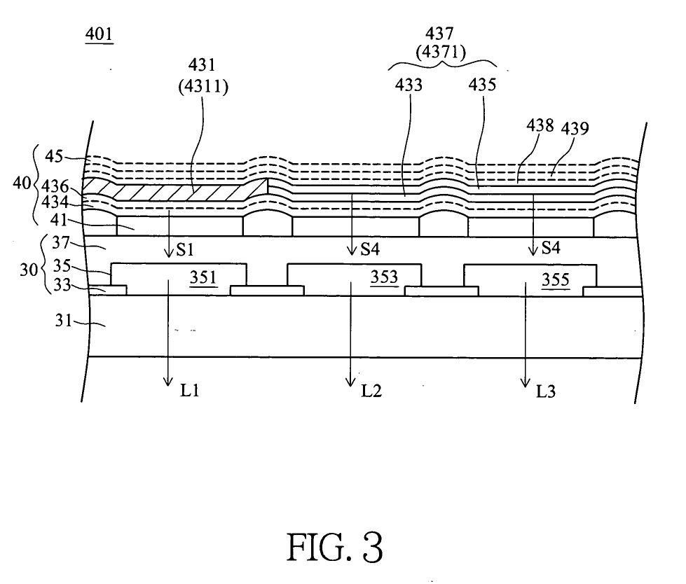

Referring to FIG. 3 for a schematic cross sectional view of another embodiment of the present invention, the organic electroluminescent display device 401 comprises an organic light emitting element 40 on the surface of the color filter 30. The first organic light emitting unit 431 provided on the vertical extension place of the first photo-resist 351, and the fourth organic light emitting unit 437 provided on the vertical extension place of the second photo-resist 353 and third photo-resist 355. The first organic light emitting unit 431 or fourth organic light emitting unit 437 is as an organic light emitting layer with a single layer or plurality of layers, such as the first organic light emitting unit 431 comprises a first organic light emitting layer 4311, and the fourth organic light emitting layer 4371 of the fourth light emitting unit 437 comprising a lamination type second organic light emitting layer 433 and third organic light emitting layer 435.

Alternatively, the first organic light emitting unit 431 or fourth organic light emitting 437 are selected by a hole injection layer 434 (HIL), hole transport layer 436(HTL), organic light emitting layer, electron transport layer 438 (ETL), and electron injection layer 439 (EIL), such as the hole injection layer 434 and hole transport layer 436 provided in turn on the surface of the first electrode 41, the first organic light emitting unit 431 and fourth organic light emitting unit 437 provided on the surface of the hole injection layer 436, and the electron transport layer 438 and electron injection layer 439 provided in turn on the surface of the first organic light emitting unit 431 and fourth organic light emitting unit 437.

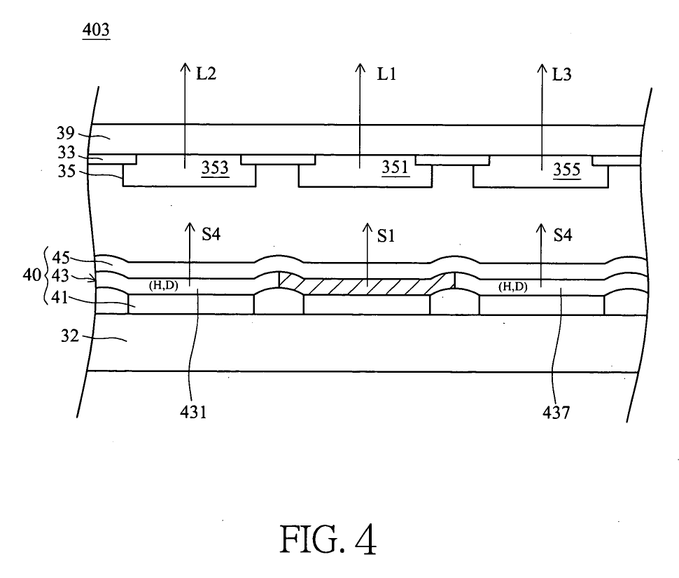

Referring to FIG. 4 for a schematic cross sectional view of another embodiment of the present invention, the organic electroluminescent display device 403 comprises at least one organic light emitting element 40 on the surface of a substrate 32, a cap 39 (or passivation layer) provided on the surface of the area uncovered the organic light emitting element 40 of the substrate 32. To completely cover the organic light emitting element 40 by the cap 39 for protecting the organic light emitting element 40. The cap 39 comprises at least one black matrix 33 on the bottom thereof, a color filtering layer (or photo-resist) 35 provided on the surface of the black matrix 33 and the partial surface of the area uncovered black matrix 33 of the cap 39. The color filtering layer 35 comprises a first photo-resist 351, second photo-resist 353, and third photo-resist 355.

A single pixel of the organic electroluminescent display device 403 comprises a first photo-resist 351, second photo-resist 353, and third photo-resist 355, respectively provided on a sub-pixel of the single pixel. The provided place of the first photo-resist 351, second photo-resist 353, and third photo-resist 355 is changeable, such as the first photo-resist 351 can be provided on the place of the both sides sub-pixel, as shown on FIG. 3; can be provided on the place of intermediate sub-pixel also, as shown on FIG. 4. Further, the first organic light emitting unit 431 and fourth organic light emitting unit 437 can be adjusted depending on the place changed of the photo-resist.

The first organic light emitting unit 431 or fourth organic light emitting unit 437 can be also selected as a dopant type organic light emitting unit with at least one host emitter H doped at least one dopant (guest emitter) D, which is also collocated to generate a colored light source.

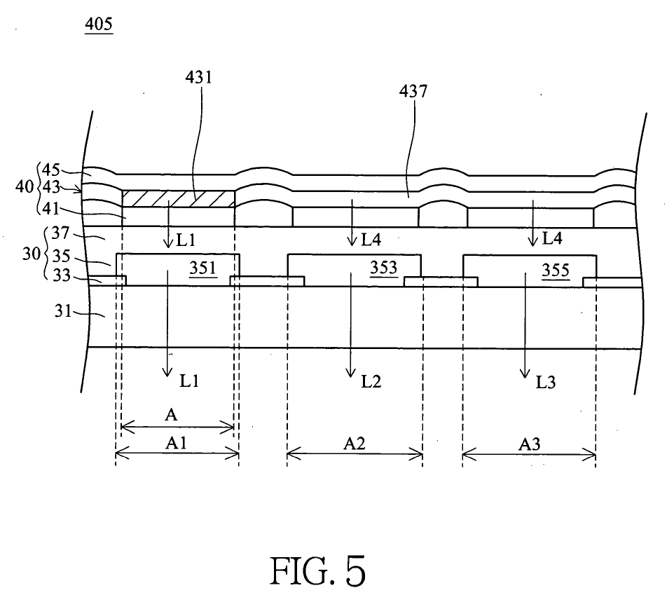

Referring to FIG. 5 for a schematic cross sectional view of another embodiment of the present invention, the organic electroluminescent display device 405 comprises at least one organic light emitting element 40 on the surface of a color filter 30, the organic light emitting unit 431 provided on the vertical extension place of the first photo-resist 351, the fourth organic light emitting unit 437 provided on the vertical extension place of the second photo-resist 353 and third photo-resist 355. And, according to the light emitting efficiency differences of the first organic light emitting unit 431 and fourth organic light emitting unit 437, adjusts the operation area of the first organic light emitting unit 431 and each photo-resist.

In view of an embodiment of the present invention, when the light emitting efficiency of the first organic light emitting unit 431 is better than the fourth organic light emitting unit 437, such as the first organic light emitting unit 431 is able to generate a green light source, the operation area of the organic light emitting layer of the first organic light emitting unit 431 can be reduced relatively, such as the operation area A of the organic light emitting layer of the first organic light emitting unit 431 is smaller than the operation area A1 of the first photo-resist 351. The first organic light emitting unit 431 is allowed to have a larger error range, so as to benefit for alignment and evaporation of the organic light emitting layer of the first organic light emitting unit 431 or mask process, and balance the intensity and decline between each colored light of the organic electroluminescent display device 405.

According to the better light emitting efficiency of the first organic light emitting unit 431, the operation area A1 of the first photo-resist 351 is able to be adjusted also, such as the operation area A1 of the first photo-resist 351 can be adjusted to be smaller than the operation area A2 or A3 of the second photo-resist 353 or third photo-resist 355.

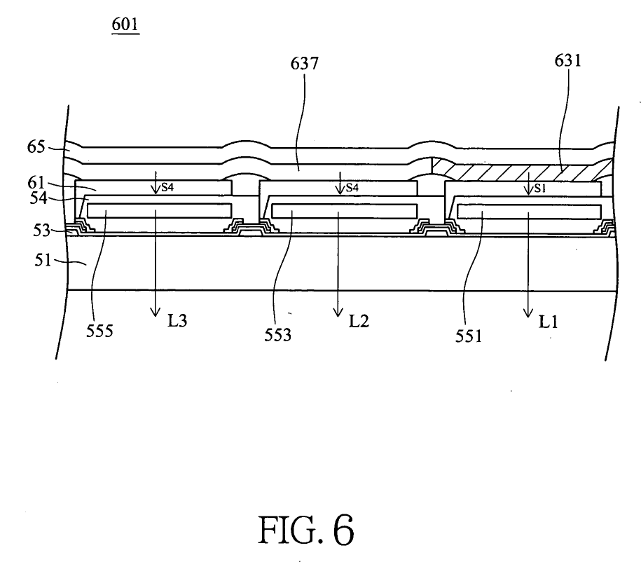

Referring to FIG. 6 for a schematic cross sectional view of another embodiment of the present invention, the organic electroluminescent display device 601 is also designed as an active matrix organic electroluminescent display device, comprising a thin film transistor (TFT) 53 on the surface of a transparent substrate 51, at least one internal passivation film 54 provided on the partial surface of the thin film transistor 53 and transparent substrate 51, at least one first photo-resist 551, second photo-resist 553, and third photo-resist 555 provided on the internal of the internal passivation film 54, at least one first electrode 61 provided on the surface of the internal passivation film 54, wherein the first electrode 61 is electrically connected to the corresponding thin film transistor 53.

The first organic light emitting unit 631 is used to generate a first light S1, provided on the surface of the first electrode 61 of the vertical extension place of the first photo-resist 551. The fourth organic light emitting unit 637 is used to generate a fourth light S4, provided on the surface of the first electrode 61 of the vertical extension place of the second photo-resist 553 and third photo-resist 555. The first organic light emitting unit 631 is placed on the surface of the partial first electrode 61, and the fourth organic light emitting unit 637 is placed on the surface of the first electrode 61 without the first organic light emitting unit 631 provided. Further, at least one second electrodes 65 are provided on the partial surface of the first organic light emitting unit 631 and fourth organic light emitting unit 637. Therefore, to form an active matrix organic electroluminescent display device with color filter on array (COA) is achieved.

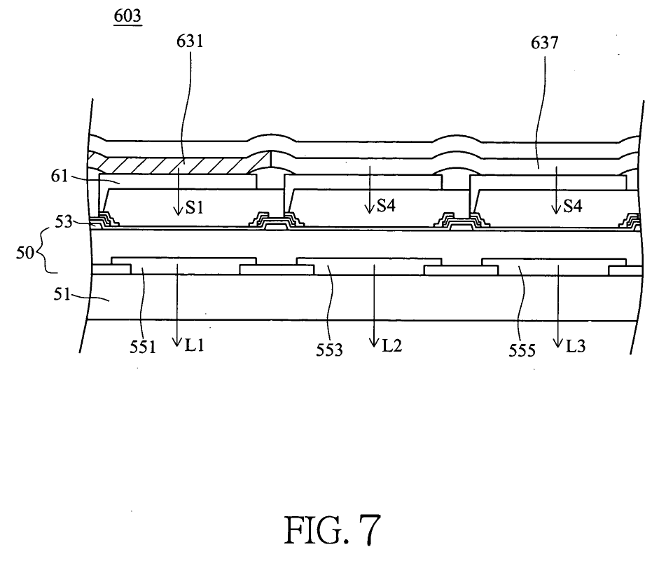

Referring to FIG. 7 for a schematic cross sectional view of another embodiment of the present invention, the active matrix organic electroluminescent display device 603 comprises a first photo-resist 551, second photo-resist 553, and third photo-resist 555 on the surface of the transparent substrate 51 to form a color filter 50. The thin film transistor 53 is provided on the partial surface of the color filter 50. A first organic light emitting unit 631 provided on the surface of the first electrode 61 of the vertical extension place of the first photo-resist 551. A fourth organic light emitting unit 637 provided on the surface of the first electrode 61 of the vertical extension place of the second photo-resist 553 and third photo-resist 555. Thus, to filter the first light S1 and fourth light S4 by the first photo-resist 551, second photo-resist 553, and third photo-resist 555 for showing a full-color display effect on the active matrix organic electroluminescent display device 603 is achieved. The fourth organic light emitting layer of the fourth organic light emitting unit 637 is able to generate a fourth light S4, so as to form an array on color filter (AOC) structure.

In view of an embodiment of the present invention, a cap (not shown) is provided on the partial surface of the transparent substrate 51. The first photo-resist 551, second photo-resist 553, and third photo-resist 555 are provided on the bottom of the cap. Thus, the top emitting by the active matrix organic electroluminescent display device is achieved.

In summary, it is appreciated that the present invention is related to an organic electroluminescent display device and more particularly to a full color organic electroluminescent display device with low power consumption, not only improving the light transmission and color saturation, but also reducing power consumption and extending the element lifetime thereof.

The invention has been described in detail with particular reference to certain preferred embodiments thereof, but it will be understood that variations and modifications can be effected within the spirit and scope of the invention.

### LIST OF REFERENCE SYMBOLS

10 color filter
11 substrate
13 black matrix
15 color filtering layer
151 first photo-resist
153 second photo-resist
155 third photo-resist
17 overcoat layer
20 organic light emitting element
21 first electrode
23 organic light emitting unit
25 second electrodes
30 color filter
31 transparent substrate
32 substrate
33 black matrix
35 color filtering layer
351 first photo-resist
353 second photo-resist
355 third photo-resist
37 overcoat layer
39 cap
40 organic light emitting unit
41 first electrode
43 organic light emitting unit
431 first organic light emitting unit
4311 first light emitting layer
433 second light emitting layer
434 hole injection layer
435 third organic light emitting layer
436 hole transport layer
437 fourth organic light emitting unit
4371 fourth organic light emitting layer
438 electron transport layer
439 electron injection layer
45 second electrodes
50 color filter
51 transparent substrate
53 thin film transistor
54 internal passivation film
551 first photo-resist
553 second photo-resist
555 third photo-resist
61 first electrode
631 first organic light emitting unit
637 fourth organic light emitting unit
65 second electrode
200 organic electroluminescent display device
400 organic electroluminescent display device
401 organic electroluminescent display device
403 organic electroluminescent display device
405 organic electroluminescent display device
601 active matrix organic electroluminescent display device
603 active matrix organic electroluminescent display device

What is claimed is:

1. An full-color organic electroluminescent display device with low power consumption, comprising:
a color filter comprising a first photo-resist, second photo-resist, and third photo-resist provided on the partial surface of a transparent substrate;
a first electrode provided on the partial surface of said color filter;
a first organic light emitting unit provided on the surface of said first electrode of the vertical extension place of said first photo-resist;
a fourth organic light emitting unit provided on the surface of said first electrode of the vertical extension place of said second photo-resist and third photo-resist; and
a second electrode provided on the partial surface of said first organic light emitting unit and fourth organic light emitting unit.

2. The display device of claim 1, wherein said transparent substrate further comprises an cap provided on the partial surface thereof, a corresponding first photo-resist, second photo-resist, and third photo-resist provided on the bottom of said cap.

3. The display device of claim 2, wherein said cap is also a passivation layer.

4. The display device of claim 1 further comprising at least one thin film transistor on the partial surface of said color filter, an internal passivation film and at least one first electrode provided on the partial surface of said thin film transistor and said color filter.

5. The display device of claim 4, wherein said transparent substrate comprises a cap on the partial surface thereof, a first photo-resist, second photo-resist, and third photo-resist provided on the bottom of said cap.

6. The display device of claim 1, wherein the light emitting efficiency of said first organic light emitting unit is better than said fourth organic light emitting unit.

7. The display device of claim 6, wherein the operation area of said first organic light emitting unit is smaller than said fourth organic light emitting unit.

8. The display device of claim 6, wherein the operation area of said first photo-resist is smaller than one of said second photo-resist and third photo-resist.

9. The display device of claim 1, wherein said first organic light emitting unit and first photo-resist are selectively provided on one of both sides sub-pixel and intermediate sub-pixel of a pixel.

10. The display device of claim 1, wherein one of said first organic light emitting unit, fourth organic light emitting unit, and the combination thereof are selectively consisted by one of a single layer organic light emitting unit, plurality of laminated layers organic light emitting unit, and dopant type organic light emitting unit.

11. The display device of claim 1, wherein the internal of said fourth organic light emitting unit comprises a lamination within a second organic light emitting layer and third light emitting layer.

12. The display device of claim 1, wherein said first organic light emitting and fourth organic light emitting unit are respectively selected by one of a hole injection layer, hole transport layer, organic light emitting layer, electron transport layer, electron injection layer and the combination thereof.

13. The display device of claim 1, wherein said first organic light emitting unit and fourth organic light emitting unit respectively generate a first light and fourth light, said first light passing through said first photo-resist filtered into a first colored light, said fourth light passing through said second photo-resist and third photo-resist filtered into a corresponding second colored light and third colored light.

14. The display device of claim 13, wherein said first light is green light, said fourth light is selected by one of white light, purple light, and magenta light.

15. The display device of claim 13, said first light and fourth light are complementary.

16. The display device of claim 1, wherein said color filter further comprises one of at least one black matrix, overcoat layer, barrier layer, and the combination thereof.

17. An full-color organic electroluminescent display device with low power consumption, comprising:
a substrate;
a first electrode provided on the partial surface of said substrate;
a first organic light emitting unit provided on the surface of said first electrode;
a fourth organic light emitting unit provided on the surface of said first electrode;
a second electrode provided on the partial surface of said first organic light emitting unit and fourth organic light emitting unit; and
a cap provided on the said substrate comprising a first photo-resist, a second photo-resist and a third photo-resist;
wherein said first organic light emitting unit is provided on the vertical extension place of said first photo-resist, and said fourth organic light emitting unit is provided on the vertical extension place of said second photo-resist and third photo-resist.

18. The display device of claim 17 further comprising at least one thin film transistor on the partial surface of said substrate, an internal passivation film and a first electrode provided on the partial surface of said thin film transistor and said substrate.

19. An full-color organic electroluminescent display device with low power consumption, comprising:
a transparent substrate;
at least one thin film transistor provided on the partial surface of said transparent substrate;
an internal passivation film and a first electrode provided on the partial surface of said thin film transistor and said transparent substrate;
a first photo-resist, second photo-resist, and third photo-resist provided on the internal of said internal passivation film;
a first organic light emitting unit provided on the surface of said first electrode of the vertical extension place of said first photo-resist;
a fourth organic light emitting unit provided on the surface of said first electrode of the vertical extension place of said second photo-resist and third photo-resist; and
a second electrode provided on the partial surface of said first organic light emitting unit and fourth organic light emitting unit.

20. The display device of claim 19, wherein said transparent substrate comprises a cap on the partial surface thereof, a first photo-resist, second photo-resist, and third photo-resist provided on the bottom of said cap.
